(19) United States
(12) Patent Application Publication
(10) Pub. No.: US 2025/0322899 A1
(43) Pub. Date: Oct. 16, 2025

(54) NONVOLATILE MEMORY CELL TRACKING USING BLOOM FILTERS

(71) Applicant: SanDisk Technologies LLC, Austin, TX (US)

(72) Inventors: Lunkai Zhang, Portland, OR (US); Nathan Franklin, Belmont, CA (US)

(73) Assignee: SanDisk Technologies LLC, Austin, TX (US)

(21) Appl. No.: 18/631,167

(22) Filed: Apr. 10, 2024

(51) Int. Cl. G11C 29/52; G11C 13/00

(52) U.S. Cl. CPC G11C 29/52; G11C 13/004; G11C 13/0069

(57) ABSTRACT

An apparatus includes one or more control circuit configured to connect to a nonvolatile memory cell structure. The one or more control circuit is configured to receive a plurality of write commands specifying write addresses in the nonvolatile memory cell structure. The one or more control circuit is configured to apply a plurality of Bloom filters to the write addresses, each Bloom filter corresponding to a respective period. Each Bloom filter has a plurality of hash functions to be applied to write addresses received in the respective period of the Bloom filter to generate hashes to populate the Bloom filter.

### BACKGROUND

Memory is widely used in various electronic devices such as cellular telephones, digital cameras, personal digital assistants, medical electronics, mobile computing devices, non-mobile computing devices, and data servers. Memory may comprise nonvolatile memory or volatile memory. A nonvolatile memory allows information to be stored and retained even when the nonvolatile memory is not connected to a source of power (e.g., a battery).

Examples of nonvolatile memory include ReRAM memories (resistive random access memories), magnetoresistive memory (e.g., MRAM, Spin Transfer Torque MRAM, Spin Orbit Torque MRAM), FeRAM (Ferroelectric random access memory), phase change memory (e.g., PCM), Selector-Only Memory (SOM), and the like.

Various phenomena may cause errors in data stored in nonvolatile memory including ReRAM, MRAM, FeRAM, PCM, SOM and other memory. Error Correction Code (ECC) may be used to correct such errors. Correcting errors using ECC may require significant resources and take significant time. In some cases, data may have too many errors to correct using a given ECC scheme. Such data may be considered Uncorrectable by ECC or “UE.” For example, in some cases, characteristics of memory cells may change after memory cells are written (programmed) so that data written in such memory cells may be incorrectly read (e.g., the error rate when data is subsequently read may be high). In the example of resistive memory, memory cell resistance may change (e.g., increase) after writing so that accurately reading resistive memory cells at different times after writing may be challenging.

### BRIEF DESCRIPTION OF THE DRAWING

Like-numbered elements refer to common components in the different figures.

FIG. 1 is a block diagram of one embodiment of a memory system connected to a host.

FIG. 2 is a block diagram of one embodiment of a Front End Processor Circuit. In some embodiments, the Front End Processor Circuit is part of a Controller.

FIG. 3 is a block diagram of one embodiment of a Back End Processor Circuit. In some embodiments, the Back End Processor Circuit is part of a Controller.

FIG. 4 is a block diagram of one embodiment of a memory package.

FIG. 5 is a block diagram of one embodiment of a memory die.

FIG. 6 illustrates an example of control circuits on a control die coupled to a memory structure on a memory die.

FIG. 7A depicts one embodiment of a portion of a memory array that forms a cross-point architecture in an oblique view.

FIGS. 7B and 7C respectively present side and top views of the cross-point structure in FIG. 7A.

FIG. 7D depicts an embodiment of a portion of a two level memory array that forms a cross-point architecture in an oblique view.

FIG. 8 illustrates an example of resistive memory cells in two data states.

FIG. 9 illustrates an example of changing memory cell resistance after writing.

FIG. 10 illustrates an example of a system that includes control circuits connected to a resistive memory structure.

FIGS. 11A-B illustrate an example of a plurality of Bloom filters used to track elapsed time since writing data in a resistive memory structure.

FIG. 12 illustrates an example of a plurality of Bloom filters used to track elapsed time since writing data in a resistive memory structure.

FIGS. 13A-D illustrate the operation of a Bloom filter with addresses in a memory structure.

FIG. 14 illustrates an example of a method that includes applying Bloom filters to write addresses.

FIGS. 15A-C illustrate examples of methods that include applying Bloom filters to read addresses.

FIG. 16 illustrates an example of a method that includes selecting one or more read parameter according to a time period associated with a Bloom filter.

### DETAILED DESCRIPTION

In some memory cell structures, memory cells that are written (e.g., programmed to store data) may not remain stable over time after a write operation. For example, in a resistive memory, resistance of memory cells may change after a write operation (e.g., following a logarithmic curve that tends to stabilize over time). Because of such change or “resistance drift” the same read parameters may not be optimized for reads at different times, which may result in unacceptably high error rates if read parameters are unchanged.

In some cases, different read parameters may be used at different times (e.g., two or more different read parameters depending on elapsed time since a write operation). For example, where resistance of a memory cell is read by comparing voltage across the memory cell with a reference voltage while a constant current is applied, two or more different reference voltages may be used according to elapsed time since a write operation. Where different data is written at different times, some form of tracking may be used to record when different portions of data were written. While timestamps may be used to indicate a time of each write operation, this may be burdensome and inefficient (e.g., it may require significant space to store a timestamp for every address written).

Aspects of the present technology are directed to technical problems associated with tracking write operations in a nonvolatile memory cell array in an efficient manner (e.g., so that appropriate read parameters may be used when reading data). Technical solutions provided by the present technology include applying a plurality of Bloom filters to write addresses received with write commands (e.g., applying a plurality of hash functions to each write address and saving the hashes in a current or active Bloom filter at the time of writing). Different Bloom filters may be applied at different times (e.g., each Bloom filter is active in a respective period and is subsequently archived). When a read command is received with a read address, the Bloom filters (active and archived) are checked to see if the read address corresponds to a write address in any Bloom filter (e.g., hash functions are applied to read address and the results are compared with each Bloom filter). Read parameters may be selected according to whether a Bloom filter hit or miss occurs (e.g., a Bloom filter hit may indicate a relatively short elapsed time since a write operation so that a read operation may use a relatively low reference voltage while a Bloom filter miss for all Bloom filters indicates a relatively long elapsed time since a write operation so that a read operation may use a relatively high reference voltage). Bloom filters may be associated with different timespans so that the Bloom filter in which a hit occurs may indicate elapsed time since writing.

Bloom filters populated with hashes of write addresses represent an efficient way of storing information regarding periods in which various write operations were performed. Such Bloom filters may be rapidly and efficiently used to check elapsed time since writing data at a read address received in a read command so that appropriate read parameters may be used.

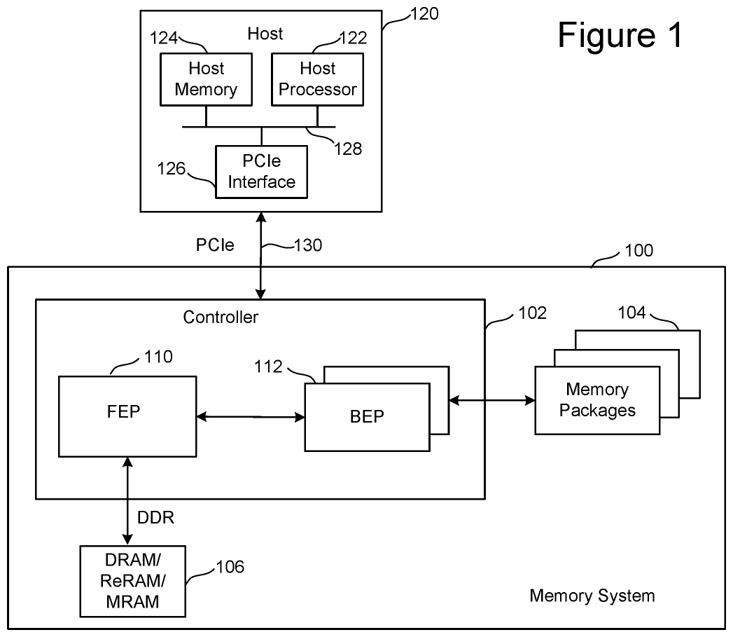

FIG. 1 is a block diagram of one embodiment of a memory system 100 connected to a host 120. Memory system 100 can implement the technology presented herein for managing error rates. Many different types of memory systems can be used with the technology proposed herein. Example memory systems include solid state drives (“SSDs”), memory cards including dual in-line memory modules (DIMMs) for DRAM replacement, and embedded memory devices; however, other types of memory systems can also be used.

Memory system 100 of FIG. 1 comprises a controller 102, nonvolatile memory 104 for storing data, and local memory (e.g., DRAM/ReRAM/MRAM) 106. Controller 102 comprises a Front End Processor (FEP) circuit 110 and one or more Back End Processor (BEP) circuits 112. In one embodiment FEP circuit 110 is implemented on an Application Specific Integrated Circuit (ASIC). In one embodiment, each BEP circuit 112 is implemented on a separate ASIC. In other embodiments, a unified controller ASIC can combine both the front end and back end functions. The ASICs for each of the BEP circuits 112 and the FEP circuit 110 are implemented on the same semiconductor such that the controller 102 is manufactured as a System on a Chip (“SoC”). FEP circuit 110 and BEP circuit 112 both include their own processors. In one embodiment, FEP circuit 110 and BEP circuit 112 work as a master slave configuration where the FEP circuit 110 is the master and each BEP circuit 112 is a slave. For example, FEP circuit 110 implements a Flash Translation Layer (FTL) or Media Management Layer (MML) that performs memory management (e.g., garbage collection, wear leveling, etc.), logical to physical address translation, communication with the host, management of DRAM (local volatile memory) and management of the overall operation of the SSD (or other nonvolatile storage system). The BEP circuit 112 manages memory operations in the memory packages/die at the request of FEP circuit 110. For example, the BEP circuit 112 can carry out the read, erase, and programming processes. Additionally, the BEP circuit 112 can perform buffer management, set specific voltage levels required by the FEP circuit 110, perform error correction (ECC), control the Toggle Mode interfaces to the memory packages, etc. In one embodiment, each BEP circuit 112 is responsible for its own set of memory packages.

In one embodiment, nonvolatile memory 104 comprises a plurality of memory packages. Each memory package includes one or more memory die. Therefore, controller 102 is connected to one or more nonvolatile memory die. In one embodiment, each memory die in the memory packages 104 utilize NAND flash memory (including two dimensional NAND flash memory and/or three dimensional NAND flash memory). In other embodiments, the memory package can include other types of memory, such as storage class memory (SCM) based on resistive random access memory (such as ReRAM, MRAM, FeRAM or RRAM) or a phase change memory (PCM). In other embodiments, the BEP or FEP can be included on the memory die.

Controller 102 communicates with host 120 via an interface 130 that implements a protocol such as, for example, NVM Express (NVMe) or Compute Express Link (CXL) over PCI Express (PCIe) or using JEDEC standard Double Data Rate or Low-Power Double Data Rate (DDR or LPDDR) interface such as DDR5 or LPDDR5. For working with memory system 100, host 120 includes a host processor 122, host memory 124, and a PCIe interface 126 connected along bus 128. Host memory 124 is the host's physical memory, and can be DRAM, SRAM, MRAM, nonvolatile memory, or another type of storage. Host 120 is external to and separate from memory system 100. In one embodiment, memory system 100 is embedded in host 120.

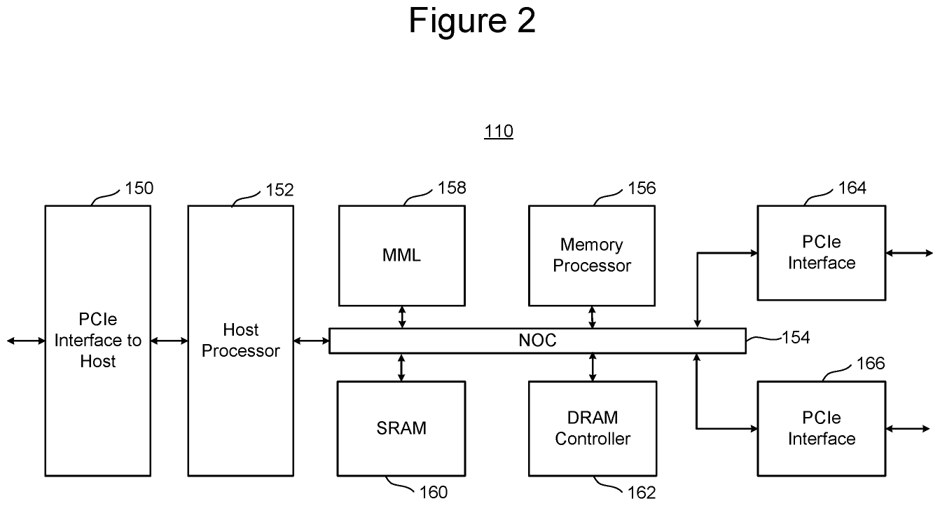

FIG. 2 is a block diagram of one embodiment of FEP circuit 110. FIG. 2 shows a PCIe interface 150 to communicate with host 120 and a host processor 152 in communication with that PCIe interface. The host processor 152 can be any type of processor known in the art that is suitable for the implementation. Host processor 152 is in communication with a network-on-chip (NOC) 154. A NOC is a communication subsystem on an integrated circuit, typically between cores in a SoC. NOCs can span synchronous and asynchronous clock domains or use unclocked asynchronous logic. NOC technology applies networking theory and methods to on-chip communications and brings notable improvements over conventional bus and crossbar interconnections. NOC improves the scalability of SoCs and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). Connected to and in communication with NOC 154 is the memory processor 156, SRAM 160 and a DRAM controller 162. The DRAM controller 162 is used to operate and communicate with the DRAM (e.g., DRAM 106). SRAM 160 is local RAM memory used by memory processor 156.

Memory processor 156 is used to run the FEP circuit and perform the various memory operations. Also, in communication with the NOC are two PCIe Interfaces 164 and 166. In the embodiment of FIG. 2, the SSD controller will include two BEP circuits 112; therefore, there are two PCIe Interfaces 164/166. Each PCIe Interface communicates with one of the BEP circuits 112. In other embodiments, there can be more or less than two BEP circuits 112; therefore, there can be more than two PCIe Interfaces.

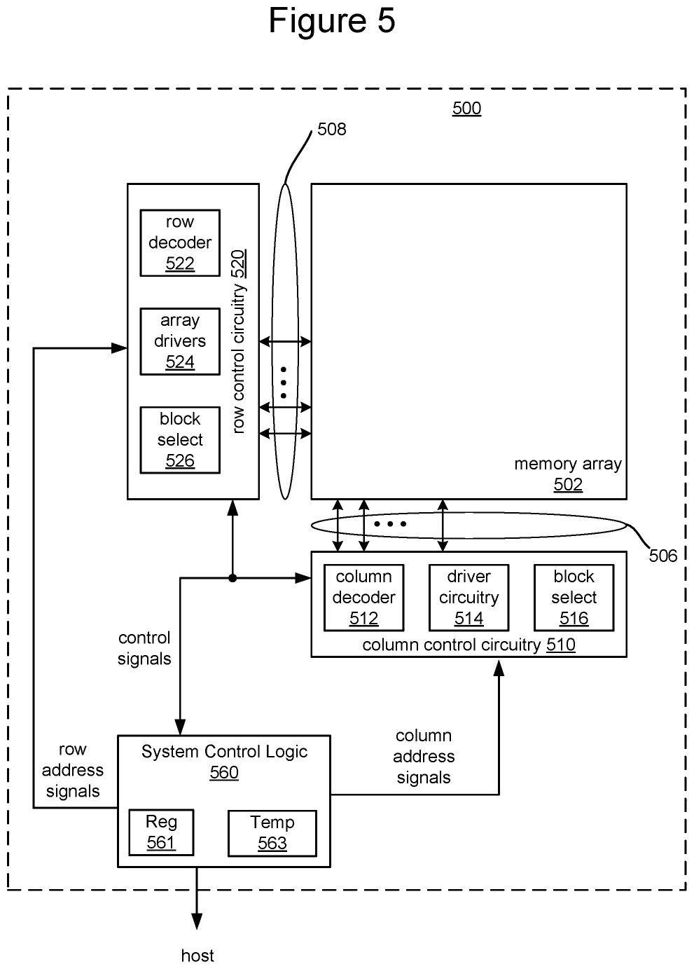

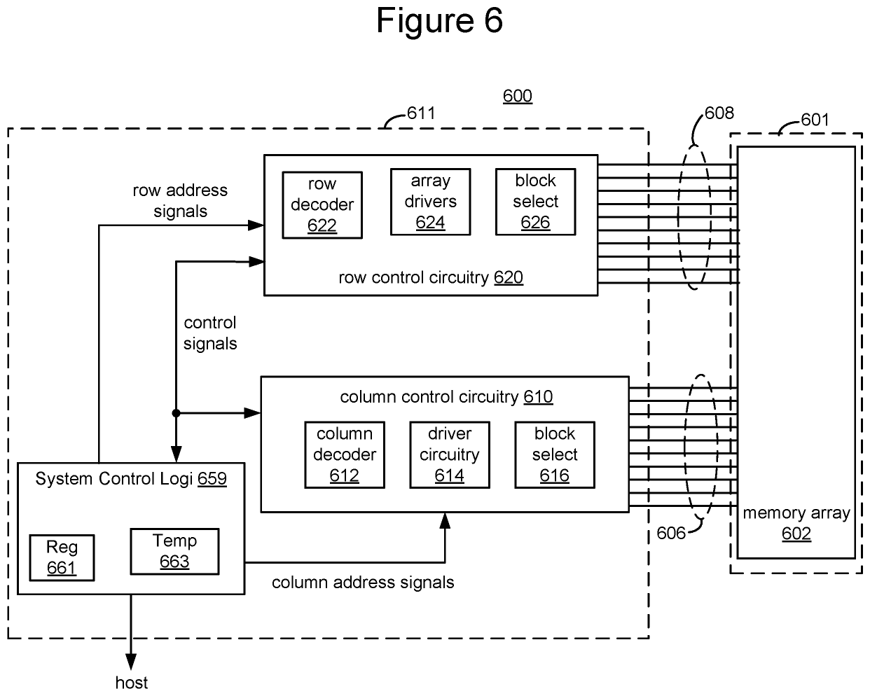

FEP circuit 110 can also include a Flash Translation Layer (FTL) or, more generally, a Media Management Layer (MML) 158 that performs memory management (e.g., garbage collection, wear leveling, load balancing, etc.), logical to physical address translation, communication with the host, management of DRAM (local volatile memory) and management of the overall operation of the SSD or other nonvolatile storage system. The media management layer MML 158 may be integrated as part of the memory management that may handle memory errors and interfacing with the host. In particular, MML may be a module in the FEP circuit 110 and may be responsible for the internals of memory management. In particular, the MML 158 may include an algorithm in the memory device firmware which translates writes from the host into writes to the memory structure (e.g., 502/602 of FIGS. 5 and 6 below) of a die. The MML 158 may be needed because: 1) the memory may have limited endurance; 2) the memory structure may only be written in multiples of pages; and/or 3) the memory structure may not be written unless it is erased as a block. The MML 158 understands these potential limitations of the memory structure which may not be visible to the host. Accordingly, the MML 158 attempts to translate the writes from host into writes into the memory structure.

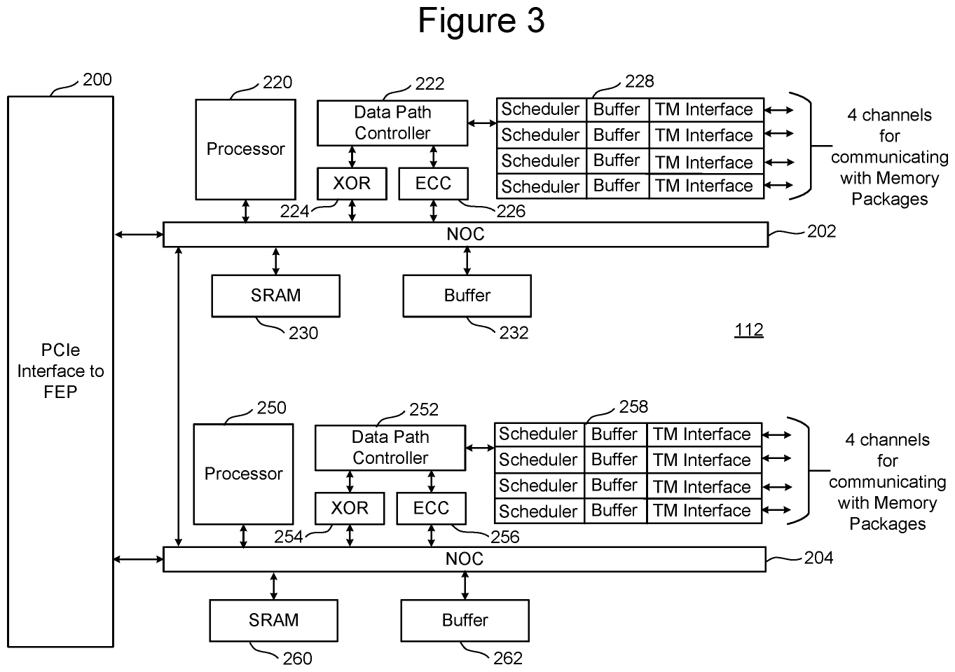

FIG. 3 is a block diagram of one embodiment of the BEP circuit 112. FIG. 3 shows a PCIe Interface 200 for communicating with the FEP circuit 110 (e.g., communicating with one of PCIe Interfaces 164 and 166 of FIG. 2). PCIe Interface 200 is in communication with two NOCs 202 and 204. In one embodiment the two NOCs can be combined into one large NOC. Each NOC (202/204) is connected to SRAM (230/260), a buffer (232/262), processor (220/250), and a data path controller (222/252) via an XOR engine (224/254) and an ECC engine (226/256). The ECC engines 226/256 are used to perform error correction, as known in the art. The XOR engines 224/254 are used to XOR the data so that data can be combined and stored in a manner that can be recovered in case there is a programming error. Data path controller 222 is connected to an interface module for communicating via four channels with memory packages. Thus, the top NOC 202 is associated with an interface 228 for four channels for communicating with memory packages and the bottom NOC 204 is associated with an interface 258 for four additional channels for communicating with memory packages. Each interface 228/258 includes four Toggle Mode interfaces (TM Interface), four buffers and four schedulers. There is one scheduler, buffer, and TM Interface for each of the channels. The processor can be any standard processor known in the art. The data path controllers 222/252 can be a processor, FPGA, microprocessor, or other type of controller. The XOR engines 224/254 and ECC engines 226/256 are dedicated hardware circuits, known as hardware accelerators. In other embodiments, the XOR engines 224/254 and ECC engines 226/256 can be implemented in software. The scheduler, buffer, and TM Interfaces are hardware circuits.

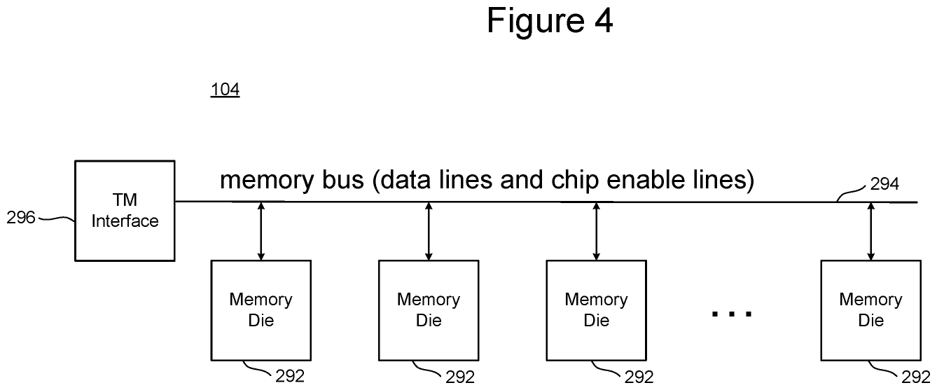

FIG. 4 is a block diagram of one embodiment of a memory package 104 that includes a plurality of memory die 292 connected to a memory bus (data lines and chip enable lines) 294. The memory bus 294 connects to a Toggle Mode Interface 296 for communicating with the TM Interface of a BEP circuit 112 (see e.g., FIG. 3). In some embodiments, the memory package can include a small controller connected to the memory bus and the TM Interface. The memory package can have one or more memory die. In one embodiment, each memory package includes eight or 16 memory die; however, other numbers of memory die can also be implemented. In another embodiment, the Toggle Interface is instead JEDEC standard DDR or LPDDR with or without variations such as relaxed time-sets or smaller page size. The technology described herein is not limited to any particular number of memory die.

FIG. 5 is a block diagram that depicts one example of a memory system 500 that can implement the technology described herein. Memory system 500 includes a memory array 502 that can include any of memory cells described in the following. The array terminal lines of memory array 502 include the various layer(s) of word lines organized as rows, and the various layer(s) of bit lines organized as columns. However, other orientations can also be implemented. Memory system 500 includes row control circuitry 520, whose outputs 508 are connected to respective word lines of the memory array 502. Row control circuitry 520 receives a group of M row address signals and one or more various control signals from system control logic circuit 560, and typically may include such circuits as row decoders 522, array terminal drivers 524 (e.g., word line drivers), and block select circuitry 526 for both reading and writing operations. Memory system 500 also includes column control circuitry 510 whose input/outputs 506 are connected to respective bit lines of the memory array 502. Although only a single block is shown for memory array 502, a memory die can include multiple arrays or “tiles” that can be individually accessed. Column control circuitry 510 receives a group of N column address signals and one or more various control signals from System Control Logic 560, and typically may include such circuits as column decoders 512, array terminal receivers or drivers 514 (e.g., bit line drivers), block select circuitry 516, as well as read/write circuitry, and I/O multiplexers.

System control logic 560 receives data and commands from a host and provides output data and status to the host. In other embodiments, system control logic 560 receives data and commands from a separate controller circuit and provides output data to that controller circuit, with the controller circuit communicating with the host. In some embodiments, the system control logic 560 can include a state machine that provides die-level control of memory operations. In one embodiment, the state machine is programmable by software. In other embodiments, the state machine does not use software and is completely implemented in hardware (e.g., electrical circuits). In another embodiment, the state machine is replaced by a micro-controller, with the micro-controller either on or off the memory chip. The system control logic 560 can also include a power control module, which controls the power and voltages supplied to the rows and columns of the memory array 502 during memory operations and may include charge pumps and regulator circuit for creating regulating voltages. System control logic 560 may include one or more state machines, registers and other control logic for controlling the operation of memory system 500. FIG. 5 illustrates such registers at 561, which, for example, can be used to record data such as settings that may be used when accessing (e.g., reading or writing) memory cells of memory array 502. System control logic 560 includes temperature measurement circuit 563 which may have a temperature transducer and may generate temperature measurement values from temperature sensing by the transducer (e.g., from measurement of a current, voltage, resistance or other metric or some combination of metrics). Temperature measurement values obtained by temperature measurement circuit 563 may be sent to other components of system control logic 560 and/or memory system 500, which may use the temperature measurement values (e.g., to adjust certain parameters according to temperature).

In some embodiments, all of the elements of memory system 500, including the system control logic 560, can be formed as part of a single die. In other embodiments, some or all of the system control logic 560 can be formed on a different die.

For purposes of this document, the phrase “one or more control circuits” can include a controller, a state machine, a micro-controller and/or other control circuitry as represented by the system control logic 560 and/or other analogous circuits that are used to control nonvolatile memory.

In one embodiment, memory structure 502 comprises a three dimensional memory array of nonvolatile memory cells in which multiple memory levels are formed above a single substrate, such as a wafer. The memory structure may comprise any type of nonvolatile memory that are monolithically formed in one or more physical levels of memory cells having an active area disposed above a silicon (or other type of) substrate. In one example, the nonvolatile memory cells comprise vertical NAND strings with charge-trapping.

In another embodiment, memory structure 502 comprises a two dimensional memory array of nonvolatile memory cells. In one example, the nonvolatile memory cells are NAND flash memory cells utilizing floating gates. Other types of memory cells (e.g., NOR-type flash memory) can also be used.

The exact type of memory array architecture or memory cell included in memory structure 502 is not limited to the examples above. Many different types of memory array architectures or memory technologies can be used to form memory structure 326. No particular nonvolatile memory technology is required for purposes of the new claimed embodiments proposed herein. Other examples of suitable technologies for memory cells of the memory structure 502 include ReRAM memories (resistive random access memories), magnetoresistive memory (e.g., MRAM, Spin Transfer Torque MRAM, Spin Orbit Torque MRAM), FeRAM, phase change memory (e.g., PCM), SOM, and the like. Examples of suitable technologies for memory cell architectures of the memory structure 502 include two dimensional arrays, three dimensional arrays, cross-point arrays, stacked two dimensional arrays, vertical bit line arrays, and the like.

One example of a cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data using magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a programming current pulse. Note that the use of “pulse” in this document does not require a square pulse but includes a (continuous or non-continuous) vibration or burst of sound, current, voltage light, or other wave. Said memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 5 can be grouped into two parts, the structure of memory structure 502 of the memory cells and the peripheral circuitry, including all of the other elements. An important characteristic of a memory circuit is its capacity, which can be increased by increasing the area of the memory die of memory system 500 that is given over to the memory structure 502; however, this reduces the area of the memory die available for the peripheral circuitry. This can place quite severe restrictions on these peripheral elements. For example, the need to fit sense amplifier circuits within the available area can be a significant restriction on sense amplifier design architectures. With respect to the system control logic 560, reduced availability of area can limit the available functionalities that can be implemented on-chip. Consequently, a basic trade-off in the design of a memory die for the memory system 500 is the amount of area to devote to the memory structure 502 and the amount of area to devote to the peripheral circuitry.

Another area in which the memory structure 502 and the peripheral circuitry are often at odds is in the processing involved in forming these regions, since these regions often involve differing processing technologies and the trade-off in having differing technologies on a single die. For example, when the memory structure 502 is NAND flash, this is an NMOS structure, while the peripheral circuitry is often CMOS based. For example, elements such sense amplifier circuits, charge pumps, logic elements in a state machine, and other peripheral circuitry in system control logic 560 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 5 onto separately formed dies that are then bonded together. More specifically, the memory structure 502 can be formed on one die and some or all of the peripheral circuitry elements, including one or more control circuits, can be formed on a separate die. For example, a memory die can be formed of just the memory elements, such as the array of memory cells of flash NAND memory, MRAM memory, PCM memory, ReRAM memory, SOM memory, or other memory type. Some or all of the peripheral circuitry, even including elements such as decoders and sense amplifiers, can then be moved on to a separate die. This allows each of the memory die to be optimized individually according to its technology. For example, a NAND memory die can be optimized for an NMOS based memory array structure, without worrying about the CMOS elements that have now been moved onto a separate peripheral circuitry die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other memory circuit. Although the following will focus on a bonded memory circuit of one memory die and one peripheral circuitry die, other embodiments can use more die, such as two memory die and one peripheral circuitry die, for example.

FIG. 6 shows an alternative arrangement to that of FIG. 5, which may be implemented using to provide a bonded die pair for integrated memory assembly 600. FIG. 6 shows an example of the peripheral circuitry, including control circuits, formed in a peripheral circuit or control die 611 coupled to memory structure 602 formed in memory die 601. As with 502 of FIG. 5, the memory die 601 can include multiple independently accessible arrays or “tiles”. Common components are labelled similarly to FIG. 5 (e.g., 502 is now 602, 510 is now 610, and so on). It can be seen that system control logic 659, row control circuitry 620, and column control circuitry 610 (which may be formed by a CMOS process) are located in control die 611. Additional elements, such as functionalities from controller 102, can also be moved into the control die 611. System control logic 659, row control circuitry 620, and column control circuitry 610 may be formed by a common process (e.g., CMOS process), so that adding elements and functionalities more typically found on a memory controller 102 may require few or no additional process steps (i.e., the same process steps used to fabricate controller 102 may also be used to fabricate system control logic 659, row control circuitry 620, and column control circuitry 610). Thus, while moving such circuits from a die such as memory die of memory system 500 may reduce the number of steps needed to fabricate such a die, adding such circuits to a die such as control die 611 may not require any additional process steps.

FIG. 6 shows column control circuitry 610 on the control die 611 coupled to memory structure 602 on the memory die 601 through electrical paths 606. For example, electrical paths 606 may provide electrical connection between column decoder 612, driver circuitry 614, and block select 616 and bit lines of memory structure 602. Electrical paths may extend from column control circuitry 610 in control die 611 through pads on control die 611 that are bonded to corresponding pads of the memory die 601, which are connected to bit lines of memory structure 602. Each bit line of memory structure 602 may have a corresponding electrical path in electrical paths 606, including a pair of bonded pads, which connects to column control circuitry 610. Similarly, row control circuitry 620, including row decoder 622, array drivers 624, and block select 626, are coupled to memory structure 602 through electrical paths 608. Each electrical path 608 may correspond to a word line, dummy word line, or select gate line. Additional electrical paths may also be provided between control die 611 and memory die 601.

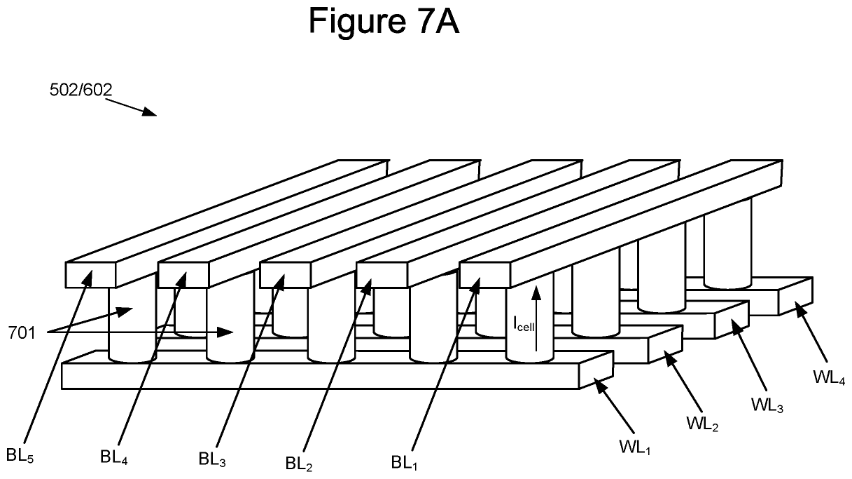

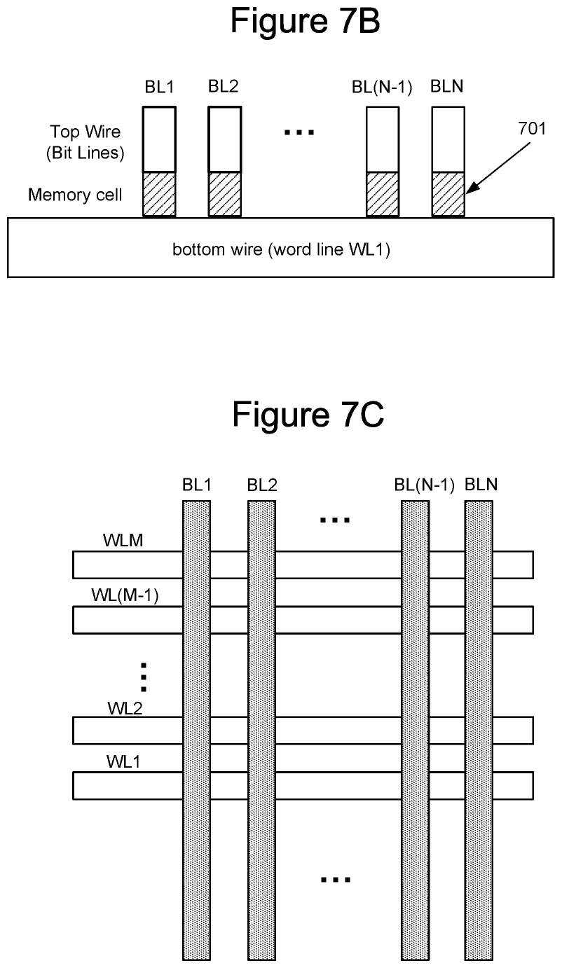

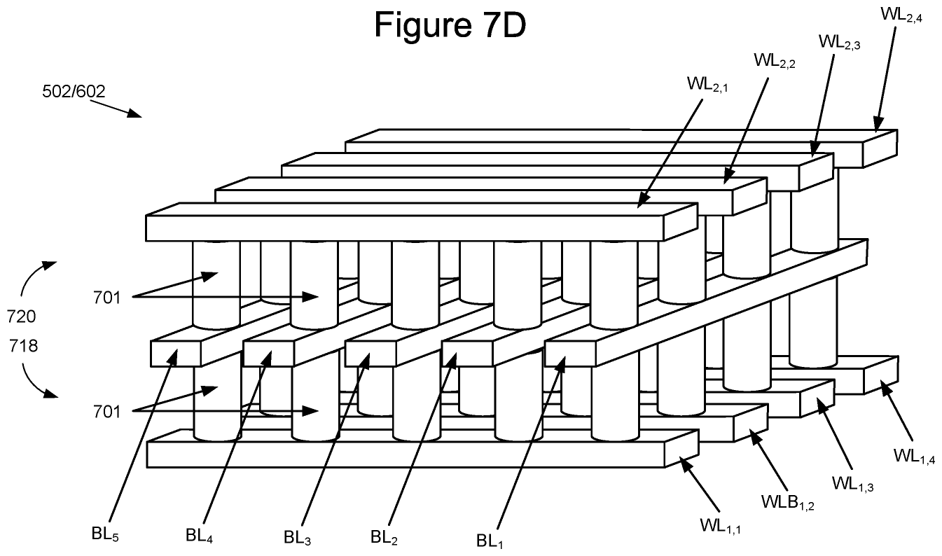

FIG. 7A depicts one embodiment of a portion of a memory array that forms a cross-point architecture in an oblique view. Memory array 502/602 of FIG. 7A is one example of an implementation for memory array 502 in FIG. 5 or 602 in FIG. 6, where a memory die can include multiple such array structures. The bit lines BL₁-BL₅ are arranged in a first direction (e.g., “bit line direction” represented as running into the page) relative to an underlying substrate (not shown) of the die and the word lines WL₁-WL₅ are arranged in a second direction (e.g., “word line direction”) perpendicular to the first direction (across the page). FIG. 7A is an example of a horizontal cross-point memory cell structure in which word lines WL₁-WL₅ and BL₁-BL₅ both run in a horizontal direction relative to the substrate, while the memory cells, two of which are indicated at 701, are oriented so that the current through a memory cell (such as shown at Icell) runs in the vertical direction. In a memory array with additional layers of memory cells, such as discussed below with respect to FIG. 7D, there would be corresponding additional layers of bit lines and word lines.

As depicted in FIG. 7A, memory array 502/602 includes a plurality of memory cells 701. The memory cells 701 may include re-writeable memory cells, such as can be implemented using ReRAM, MRAM, PCM, FeRAM, SOM, or other material with a programmable resistance. The current in the memory cells of the first memory level is shown as flowing upward as indicated by arrow Icell, but current can flow in either direction, as is discussed in more detail in the following.

FIGS. 7B and 7C respectively present side and top views of the cross-point structure in FIG. 7A. The sideview of FIG. 7B shows one bottom wire, or word line, WL₁ and the top wires, or bit lines, BL₁-BLₙ. At the cross-point between each top wire and bottom wire is a memory cell, (e.g., ReRAM, PCM, FeRAM, MRAM, SOM or other memory). FIG. 7C is a top view illustrating the cross-point memory cell structure for M bottom wires WL₁-WL_{M} and N top wires BL₁-BLN. In a binary embodiment, the memory cell at each cross-point can be programmed into one of two resistance states: high and low.

The cross-point array of FIG. 7A illustrates an embodiment with one layer (one story) of word lines and bits lines, with the memory cells sited at the intersection of the two sets of conducting lines. To increase the storage density of a memory die, two or more levels or layers (stories) of such memory cells and conductive lines can be formed. A 2-layer (2-story) example is illustrated in FIG. 7D.

FIG. 7D depicts an embodiment of a portion of a two level (two story) memory array that forms a cross-point architecture in an oblique view. As in FIG. 7A, FIG. 7D shows a first layer 718 (first story) of memory cells 701 of an array 502/602 connected at the cross-points of the first layer of word lines WL_{1,1}-WL_{1,4} and bit lines BL₁-BL₅. A second layer (second story) of memory cells 720 is formed above the bit lines BL₁-BL₅ and between these bit lines and a second set of word lines WL_{2,1}-WL_{2,4}. Although FIG. 7D shows two layers (stories), 718 and 720, of memory cells, the structure can be extended upward through additional alternating layers of word lines and bit lines. Depending on the embodiment, the word lines and bit lines of the array of FIG. 7D can be biased for read or program operations such that current in each layer flows from the word line layer to the bit line layer or the other way around. The two layers can be structured to have current flow in the same direction in each layer for a given operation, e.g. from bit line to word line for read, or to have current flow in the opposite directions, e.g. from word line to bit line for layer 1 read and from bit line to word line for layer 2 read.

In some examples, a threshold switching selector device is connected in series with the programmable resistive element. A threshold switching selector has a high resistance (in an off or non-conductive state) when it is biased to a voltage lower than its threshold voltage, and a low resistance (in an on or conductive state) when it is biased to a voltage higher than its threshold voltage. The threshold switching selector remains on until its current is lowered below a holding current, or the voltage is lowered below a holding voltage. When this occurs, the threshold switching selector returns to the off state. Accordingly, to program a memory cell at a cross-point, a voltage or current may be applied which is sufficient to turn on the associated threshold switching selector and set or reset the memory cell; and to read a memory cell, the threshold switching selector similarly must be activated by being turned on before the resistance state of the memory cell can be determined. One set of examples for a threshold switching selector is an ovonic threshold switching material of an Ovonic Threshold Switch (OTS). Aspects of the present technology may be applied to memory structures that include a selector for each memory cell and those that do not include such selectors.

The use of a cross-point architecture allows for arrays with a small footprint and several such arrays can be formed on a single die. The memory cells formed at each cross-point can be a resistive type of memory cell, where data values are encoded as different resistance levels. Depending on the embodiment, the memory cells can be binary valued, having either a low resistance state or a high resistance state, or multi-level cells (MLCs) that can have additional resistance intermediate to the low resistance state and high resistance state. The cross-point arrays described here can be used as the memory die 292 of FIG. 4, to replace local memory 106, or both.

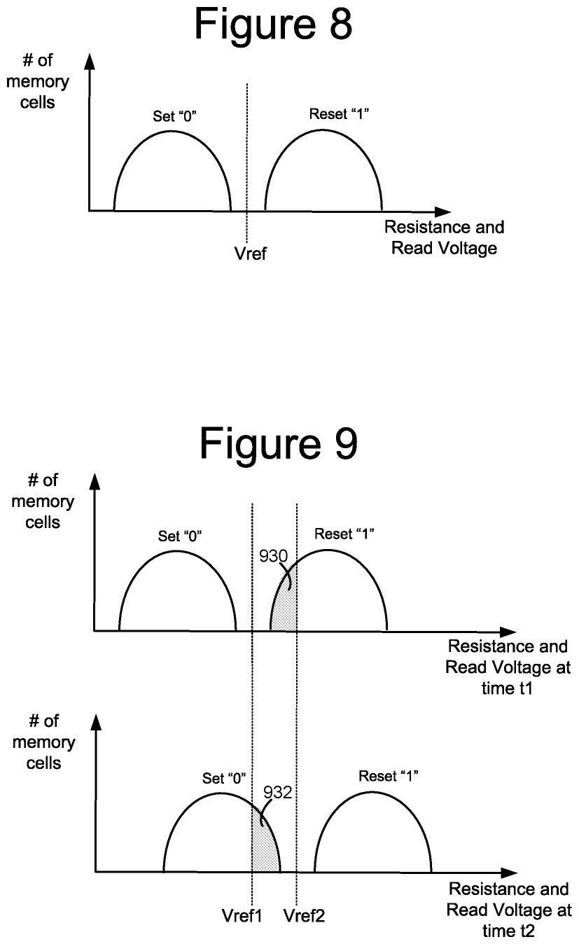

FIG. 8 illustrates an example of resistance and read voltage of a population of resistive memory cells (e.g., memory cells in a cross-point structure such as shown in FIGS. 7A-D, which may implement memory structure 502 and 602). A resistive memory cell has two distinguished resistance states that may be referred to as: “Set” (which in this example is associated with logic “0”) and “Reset” (which in this example is associated with logic “1”). In an example of a read operation, a constant read current is applied to a selected cell and the voltage across the cell (e.g., voltage difference between the selected bit line and word line connected to the selected cell) is measured (e.g., compared with a reference voltage Vref). If the voltage is lower than the reference voltage (Vref), the cell is considered in Set state. If the voltage is higher than Vref, the cell is considered in the Reset state. Ideally, the Set and Reset voltage distributions of the cells are clearly separate as illustrated in FIG. 8 with Vref located in the middle of the Set and Reset distributions. Real distributions may not be as shown in FIG. 8 (e.g., there may not be a clear separation) and the Vref value may not be at the midpoint between distributions, which may cause misreading of data and may result in errors (e.g., a high Bit Error Rate or BER).

In some cases, after data is written in resistive memory cells, the resistance of the resistive memory cells may change (e.g., there may be an increase in resistance over time). FIG. 9 shows how resistance and read voltage of a population of resistive memory cells may change over time. Resistance and read voltage at a first time, t1, is shown in the upper plot, with a first reference voltage, Vref1, located at the midpoint between the Set and Reset distributions. Resistance and read voltage at a second time, t2, is shown in the lower plot, with a second reference voltage, Vref2, located at the midpoint between the Set and Reset distributions (e.g., distributions have shifted in the direction of increasing resistance so that Vref1 is no longer at the midpoint). As a result, there is no single best Vref for times t1 and t2, (e.g., at time t1, Vref1 works well while at time t2, Vref2 works well but neither Vref1 nor Vref2 works well at both t1 and t2). For example, reading the population of memory cells with the distributions shown in the upper plot (time t1) using Vref2 results in misreading of a significant number of resistive memory cells shown by area 930 (e.g., memory cells in Reset “1” state that are read as being in Set “0” state), while reading distributions shown in the lower plot (time t2) using Vref1 also results in misreading of a significant number of resistive memory cells shown by area 932 (e.g., memory cells in Set “0” state that are read as being in Reset “1” state).

In order to accurately read resistive memory cells at different times, different reference voltages may be used according to time since writing. Resistance may change in a predictable manner after programming so that knowing the amount of time since a portion of data was written may allow suitable read parameters (e.g., a suitable value of Vref) to be selected when the portion of data is to be read. For example, a system of timestamps may be used so that individual portions of data (e.g., individual codewords) are timestamped when they are written. Subsequently, when data is to be read, the timestamp is read first and the amount of elapsed time since writing is obtained. This elapsed time may be correlated with change in resistance and read voltage so that a suitable value of Vref may be selected according to elapsed time (e.g., selecting Vref1 at time t1 and selecting Vref2 at time t2). However, recording and maintaining timestamps for every write operation and subsequently consulting recorded timestamps when performing a read operation may present a significant burden. For example, significant storage space may be required to store a timestamp and corresponding address or addresses for each codeword write operation and checking such a large structure may take significant time.

In some cases, change in resistance of resistive memory cells may be relatively rapid initially and may slow over time (e.g., resistance may follow a logarithmic curve or similar curve) so that reads occurring after a certain time (after resistance change becomes relatively slow and resistance values may be considered stable) may use the same Vref value. In some cases, two different values of Vref (e.g., Vref1 and Vref2) may be sufficient to adequately read resistive memory cells at different times after writing. In other cases, more than two values of Vref may be used (e.g., Vref1, Vref2, Vref3, . . . . Vrefn). The number of such voltages (e.g., the value of n) may depend on the characteristics of the resistive memory cells and the acceptable error rate, e.g., according to the error correction capability provided.

According to aspects of the present technology, appropriate read parameters (e.g., 2, 3, 4, or more reference voltages) may be applied according to elapsed time since writing of a portion of data without the use of timestamps or other such unnecessarily burdensome structures.

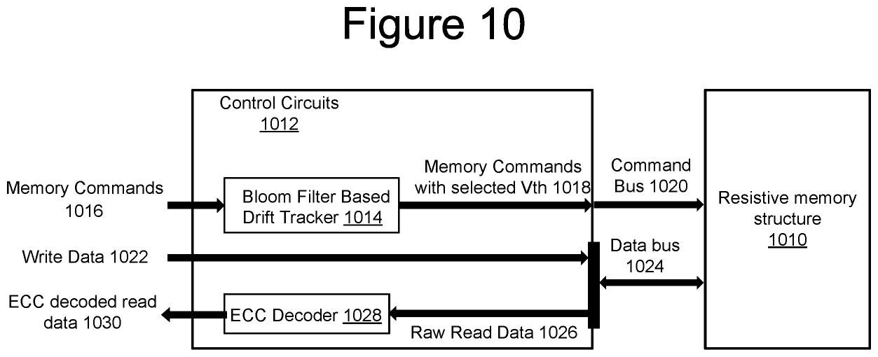

FIG. 10 shows an example of a data storage system that includes a resistive memory structure 1010 (e.g., memory structure 502/602) connected to control circuits 1012. For example, resistive memory structure 1010 may be on a memory die and control circuits 1012 may be on a memory control die, in a memory controller on a separate die, on the memory die, or some combination of these locations. Control circuits 1012 include a Bloom Filter Based Drift Tracker 1014 (“drift tracker 1014”), which may be used to track resistance drift of written data over time and provide appropriate values of Vth according to tracked drift. Drift tracker 1014 is shown receiving memory commands 1016, which may include read and write commands (e.g., from a host such as host 120), as an input and providing memory commands with selected Vth 1018 as an output (e.g., for at least some memory commands, such as read commands, a suitable value of Vth may be selected by drift tracker 1014). Memory commands are sent via command bus 1020 to resistive memory structure 1010. In parallel with write commands, write data 1022 may be received by control circuits 1012 and may be sent via data bus 1024. Raw read data 1026 (e.g., uncorrected as-read data) from resistive memory structure 1010 may also be sent via data bus 1024 to control circuits 1012 where the data is corrected by ECC Decoder 1028 (e.g., ECC engines 226, 256) to generate ECC decoded read data 1030, which may be sent to a host (e.g., host 120).

In an example of the present technology, whenever a write command is received, drift tracker 1014 uses Bloom filters to record an indicator of when the data was written (e.g., by populating different Bloom filters corresponding to different periods). Whenever a read command is received by control circuits 1012, drift tracker 1014 checks the Bloom filters to see if a read address corresponds to a write address in any Bloom filter, which may be used to indicate elapsed time since the data was written (e.g., as an indicator of how much resistive drift may have occurred). Bloom filters may be maintained for a limited period and then reused (e.g., a finite number of Bloom filters may be used in a cyclical manner). Failure to find the read address in any Bloom filter may indicate that elapsed time since writing exceeds a predetermined time (e.g., an initial time). Drift tracker 1014 may then generate an appropriate value of Vth according to elapsed time since the writing the data. For example, a Bloom filter hit may indicate relatively short elapsed time since write with correspondingly little resistive drift associated with a first reference voltage (e.g., Vref1) while a Bloom filter miss may indicate relatively long elapsed time with correspondingly greater resistive drift associated with a second reference voltage (e.g., Vref2). The value of Vth generated by drift tracker 1014 is then used to select one or more read parameter (e.g., Vref=Vref1 or Vref2) for performing a read operation directed to the read address.

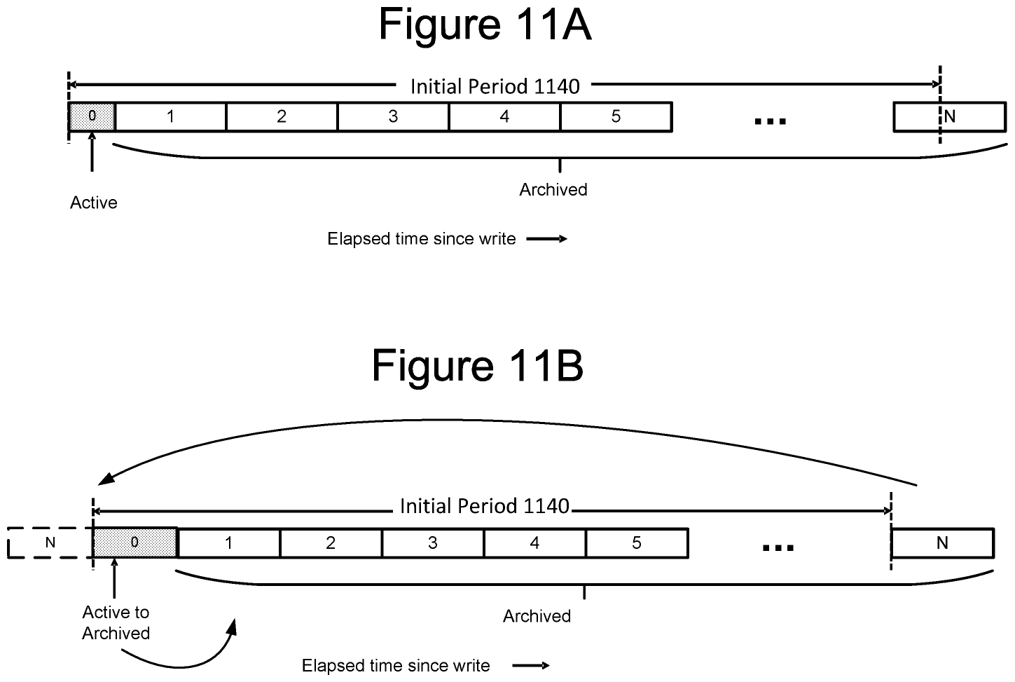

FIG. 11A illustrates an example of a plurality of Bloom filters according to an embodiment. In the example of FIG. 11A, a total of N+1 Bloom filters are used to track elapsed time from writing of data so that one or more read parameters of a subsequent read can be adjusted accordingly. FIG. 11A shows an active Bloom filter, Bloom filter 0, and additional Bloom filters including N archived Bloom filters, Bloom filters 1 to N. In this example, control circuits in a memory system (e.g., drift tracker 1014) may apply Bloom filters 0 to N for different respective time periods. In FIG. 11A, elapsed time increases to the right so that Bloom filter 1 was the active Bloom filter prior to current active Bloom filter 0, Bloom filter 2 was active prior to Bloom filter 1 and so on to Bloom filter N, which is the oldest Bloom filter in the sequence shown (additional Bloom filters may be unused and are not shown).

In an example illustrated in FIG. 11B, Bloom filters are used in a cyclical manner so that at the end of the time period of active Bloom filter 0, Bloom filter N becomes may become unused and may be initialized or erased for use as the active Bloom filter (e.g., all entries in Bloom filter N are initialized to 0). While FIG. 11B shows Bloom filter N being directly reused as the next active Bloom filter, in other examples, there may be one or more additional unused Bloom filter so that Bloom filter N may be unused for some time prior to reuse as the active Bloom filter (e.g., the next active Bloom filter may be selected from a pool of unused Bloom filters with Bloom filters added to the pool at the end of initial period 1140 and subsequently erased to generate a supply of erased Bloom filters).

The active Bloom filter is applied to all write addresses that are received. At the end of the time period of the current active Bloom filter, the current active Bloom filter is archived. After a given Bloom filter is applied to a write address, the existence of the write address in the Bloom filter may be used as an indicator of elapsed time since the data was written. For example, an address found in Bloom filter 1 was more recently written than an address found in Bloom filter 2, which was more recently written than a write address in Bloom filter 3 and so on. An address that is not found in any Bloom filter was written prior to initial period 1140 (e.g., the corresponding write address was in a Bloom filter that was erased for reuse). FIGS. 11A-B show initial period 1140, which is the period of time for which a Bloom filter is archived before it is cleared and recycled. Finding an address in any Bloom filter 0 to N may indicate that elapsed time since data was written at the corresponding address is less than initial period 1140 while failing to find an address in any Bloom filter 0 to N may indicate that elapsed time since data was written at the corresponding address is greater than initial period 1140.

In an example, one or more read parameters (e.g., a read reference voltage) may be adjusted according to elapsed time since the data was written. For example, a first read reference voltage, (e.g., Vref1) may be used when elapsed time since writing data is less than initial period 1140 (e.g., as indicated by a Bloom filter hit for at least one of Bloom filters 0 to N) while a second read reference voltage (e.g., Vref2) may be used when elapsed time since writing data is greater than initial period 1140 (e.g., as indicated by Bloom filter miss for all Bloom filters 0 to N).

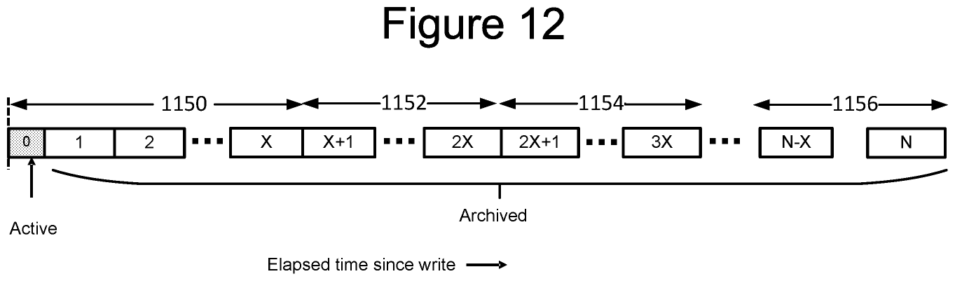

FIG. 12 shows another example of a plurality of Bloom filters according to an embodiment. As in FIG. 11, N Bloom filters are used with each Bloom filter corresponding to a respective elapsed time that increases to the right from the active Bloom filter, Bloom filter 0, to the oldest archived Bloom filter, Bloom filter N. In this example, Bloom filters are divided into different subsets associated with different timespans, which are used to identify when data was written and to adjust read parameters accordingly. For example, a first subset 1150 of Bloom filters 0 to X corresponds to a first timespan, a second subset 1152 of Bloom filters X+1 to 2X corresponds to a second timespan, a third subset 1154 of Bloom filters 2X+1 to 3X corresponds to a third timespan, and so on to a last subset 1156 of Bloom filters N—X to N, which corresponds to a last (or oldest) timespan. One or more read parameters may be selected according to whether an address of data to be read (a read address) is found in a Bloom filter and, if so, which timespan the Bloom filter corresponds to. For example, a first read reference voltage, (e.g., Vref1) may be used when reading at addresses found in Bloom filters of subset 1150, a second read reference voltage (e.g., Vref2) may be used when reading at addresses found in Bloom filters of subset 1152, a third read reference voltage (e.g., Vref3) may be used when reading at addresses found in Bloom filters of subset 1154 and so on to addresses found in Bloom filters of final subset 1156. Another reference voltage may be used when reading at addresses that are not found in any Bloom filters (e.g., a default reference voltage). The number of Bloom filters per subset/timespan may be from 1 (e.g., each Bloom filter corresponding to a timespan with different read parameters) to the total number of Bloom filters, N (e.g., as shown in the example of FIG. 11) and the number of timespans used may be chosen according to the sensitivity of memory cells to errors caused by resistive drift and/or other factors.

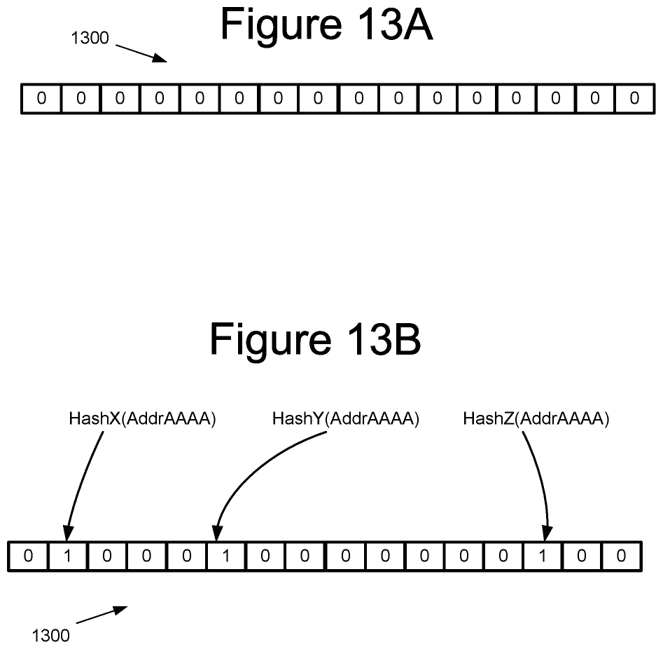

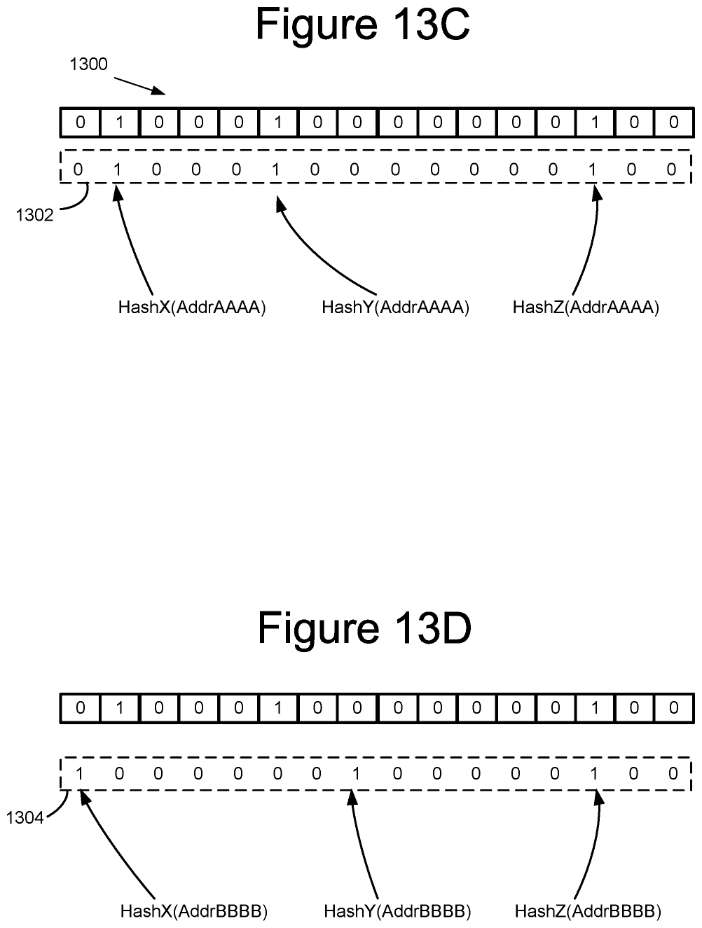

FIGS. 13A-D show a simplified example of a Bloom filter 1300 (e.g., any of Bloom filters 0 to N), which may be associated with a time period (additional Bloom filters may be associated with additional time periods). FIG. 13A shows Bloom filter 1300 as a bit array that includes m bits, where m=16 in this example (the number of bits may be configured according to requirements). Bloom filter 1300 is empty (unpopulated or erased) in FIG. 13A so that all bits are logic 0 bits. Initialization to generate an empty Bloom filter may occur prior to designating Bloom filter 1300 as the active Bloom filter (e.g., Bloom filter 1300 may have been recycled as illustrated in FIG. 11B by erasing its contents).

FIG. 13B illustrates operation of Bloom filter 1300 as the active Bloom filter when a write command is received that is directed to an address in a nonvolatile memory structure (e.g., control circuits 1012 receive memory command 1016 with address AddrAAAA in resistive memory structure 1010). A Bloom filter may be implemented using two or more hash functions (e.g., k different hash functions) to generate hashes of elements that are associated with the Bloom filter (for example, a Bloom filter may have k hash functions to be applied to write addresses received in the respective period of the Bloom filter to generate hashes to populate the Bloom filter). In the example of FIG. 13B, write addresses received in write commands within a predetermined time period associated with Bloom filter 1300 are hashed using three hash functions (e.g., k=3), HashX, HashY and HashZ. The number of hash functions used (k) and the type of hash functions may be chosen according to the number of elements expected (e.g., number of write addresses expected for Bloom filter 1300 based on frequency of write commands and time period of Bloom filter 1300), desired false error rate and/or other factors while m may be proportional to k. In some examples, k may be greater or less than 3. Additional write addresses received with write commands in additional time periods may be similarly hashed and the hashes may be stored in corresponding additional Bloom filters (e.g., Bloom filters of FIGS. 11A-B and 12).

Hashes of Bloom filter elements may be significantly smaller than the elements (e.g., HashX (AddrAAAA), HashY (AddrAAAA) and HashZ (AAAA) together may be smaller than AddrAAAA) so that the space required to record hashes of write addresses may be significantly smaller than the space required to store the write addresses. And checking a Bloom filter to verify an element is recorded in the Bloom filter may be rapidly performed (e.g., may be simpler and faster than checking an address against a list of addresses).

In FIG. 13B, each hash function of an address maps to a bit in Bloom filter 1300 so that applying Bloom filter 1300 to AddrAAAA includes applying corresponding hash functions, HashX, HashY and HashZ to AddrAAAA (and any other write addresses received in the period of Bloom filter 1300) to generate hashes that are used to populate Bloom filter 1300 as shown. While Bloom filter 1300 is applied to a single write address, AddrAAAA, in this example, a number of write addresses may be received during the period of a Bloom filter and the Bloom filter may be applied to each such address to populate the Bloom filter.

At the end of the period of a Bloom filter, the Bloom filter may cease to be the active Bloom filter and may be archived. Once a Bloom filter is archived, it may remain unchanged. New write addresses are used to populate the active Bloom filter and archived Bloom filters remain available to be read. For example, when an address is received (e.g., a read address received with a read command), the Bloom filter may be applied to the read address to see if it is an element that was used to populate the Bloom filter (e.g., a query to test if an address is an element of the set of elements associated with the Bloom filter).

FIG. 13C-D show examples in which Bloom filter 1300 is applied to read addresses at a time subsequent to the write operation of FIG. 13B, when Bloom filter 1300 remains in the state shown (e.g., either while Bloom filter 1300 remains the active Bloom filter and prior to receipt of any additional write commands or after Bloom filter 1300 transitions from active to archived).

In the example of FIG. 13C, the read address, AddrAAAA, was previously used to populate Bloom filter 1300 as shown in FIG. 13B. Accordingly, when hashes HashX, HashY and HashZ of Bloom filter 1300 are applied to AddrAAAA as shown, the resulting bit string 1302 matches the bits of Bloom filter 1300 (e.g., a “hit” occurs using AddrAAAA).

In the example of FIG. 13D, the read address, AddrBBBB, was not previously used to populate Bloom filter 1300 so that when hashes, HashX, HashY and HashZ, of Bloom filter 1300 are applied to AddrBBBB as shown, the resulting bit string 1304 does not match the bits of Bloom filter 1300 (e.g., a “miss” occurs using AddrBBBB). In this case, additional Bloom filters may be applied to AddrBBBB (e.g., bit string 1304 generated by HashX (AddrBBBB), HashY (AddrBBBB) and HashZ (AddrBBBB) may be compared with additional Bloom filters to see if AddrBBBB is an element of any Bloom filter. Bloom filters may be accessed in order (e.g., from the active Bloom filter to the oldest Bloom filter, from Bloom filter 0 to N in FIG. 11A).

While Bloom filter 1300 is shown as having a single element (AddrAAAA) in the example of FIGS. 13A-D, a Bloom filter may store multiple elements (e.g., one or more additional write addresses). Each Bloom filter in a set of Bloom filters (e.g., N+1 Bloom filters as illustrated in FIGS. 11A-12) may have multiple elements associated with a period of time when the corresponding Bloom filter was active (e.g., all write addresses during the time period are used to populate the Bloom filter). Subsequently, when a read address is received (e.g., with a read command), Bloom filters may be checked to see if the read address corresponds to an address in a Bloom filter, which may indicate the period in which the corresponding data was written at the read address (e.g., all Bloom filters may be associated with an initial period and a first read reference voltage as shown in FIGS. 11A-B, or different Bloom filters may be associated with different timespans and different read reference voltages as shown in FIG. 12). Read parameters may then be adjusted according to elapsed time since writing (e.g., alternative read parameters may be applied when Bloom filter miss occurs). For additional read addresses received with additional read commands, additional hashes are generated and compared with all Bloom filters (e.g., Bloom filter 1300 and any other active or archived Bloom filters).

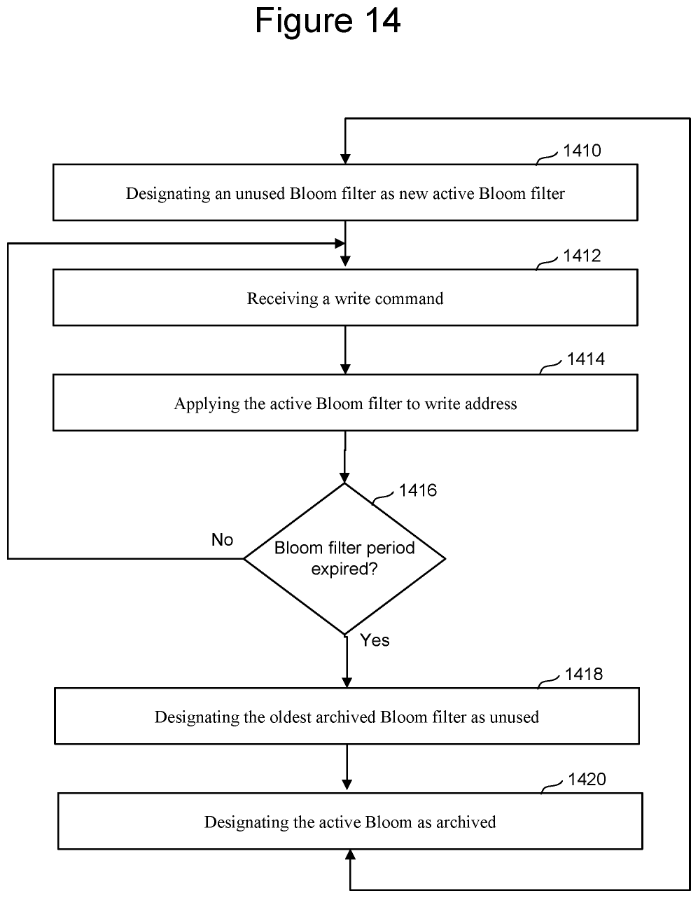

FIG. 14 shows an example of a method according to an example of the present technology that includes designating an unused Bloom filter as the new active Bloom filter 1410, receiving a write command 1412 and applying the active Bloom filter to the write command (e.g., applying hash functions and storing the results in the active Bloom filter). A determination 1416 is made as to whether the Bloom filter period is expired (e.g., a clock may record elapsed time since step 1410). If the Bloom filter period is not expired, then additional write commands may be received until the period expires. The method further includes, when the Bloom filter period expires, designating the oldest archived Bloom filter as unused 1418, designating the active Bloom filter as archived 1420 and returning to designating an unused Bloom filter as the new active Bloom filter 1410.

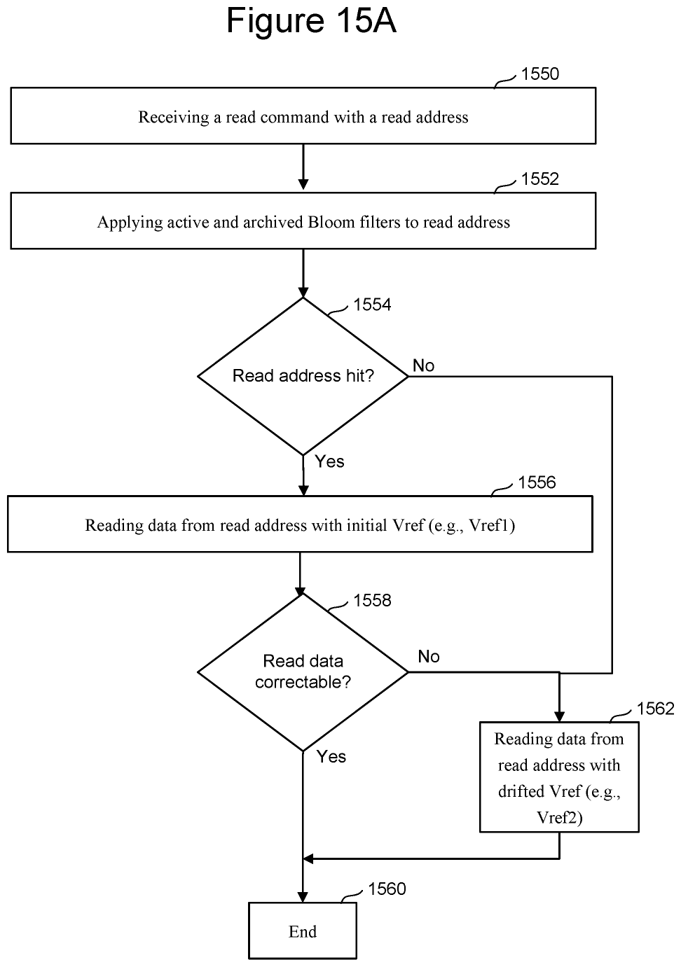

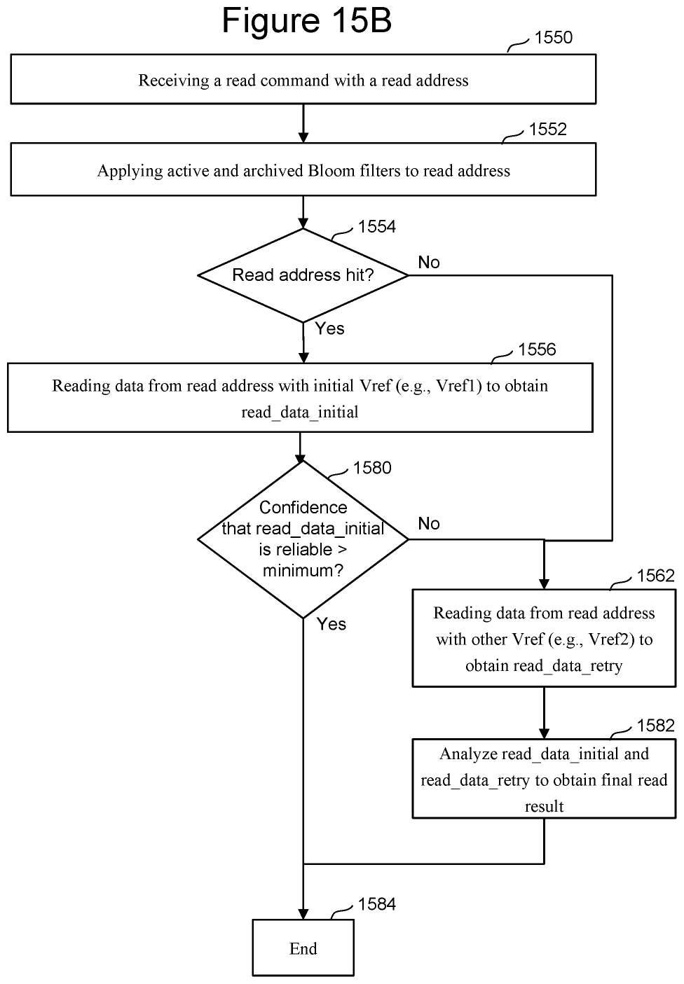

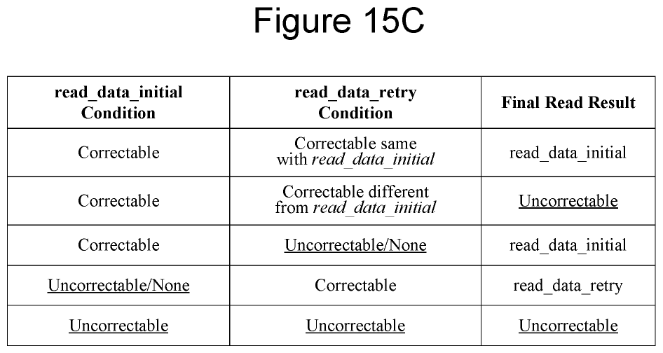

FIG. 15A shows an example of a method that includes receiving a read command with a read address 1550, applying active and archived Bloom filters to the read address 1552 and making a determination 1554 as whether there is a read address hit in any of the Bloom filters. The method further includes, when a hit occurs, reading data from the read address with an initial Vref (e.g., Vref=Vref1 1556 corresponding to initial period 1140) and determining if the read data is correctable 1558. If the read data is correctable then the operation ends 1560. If there is no read address hit in any Bloom filter or the read data is uncorrectable (or if the error rate exceeds a predetermined error rate) then the data is read from the read address with a drifted Vref (e.g., Vref2 corresponding to an elapsed time since writing of more than initial period 1140). In some cases, a Bloom filter may return a false positive result (e.g., may indicate that a specified address is found in a Bloom filter when the specified address was not used to populate the Bloom filter and no write was performed at the specified address in the period of the Bloom filter). Such false positives may not provide correctable data when read using an inappropriate reference voltage (e.g., Vref1 corresponding to initial period 1140) but may provide correctable data when read using an appropriate reference voltage (e.g., Vref2 corresponding to elapsed time greater than initial period 1140).

FIG. 15B shows another example of a method that includes receiving a read command with a read address 1550, applying active and archived Bloom filters to the read address 1552 and making a determination 1554 as whether there is a read address hit in any of the Bloom filters as in FIG. 15A. The method further includes, when a hit occurs, reading data from the read address with an initial Vref (e.g., Vref=Vref1) to obtain read_data_initial 1556. A determination 1580 is then made as to whether confidence that read data initial is reliable is greater than a minimum confidence level (e.g., whether reliability of the data read from the read address with selected (initial) Vref exceeds a minimum reliability level). In some cases, there may be one or more indication that read_data_initial is not reliable (e.g., from ECC decoding or otherwise). For example, read_data_initial may be uncorrectable (UE), may be correctable with an unacceptably high number of errors, may have an imbalance between 1s and 0s in data that should be balanced or have some other indication that it is unreliable.

If confidence that read data initial is reliable exceeds the minimum (e.g., correctable with a number of errors below a limit) then read_data_initial may be considered as the final read result (e.g., output to a host). If confidence that read_data_initial is reliable does not exceed the minimum (or if there was no read address hit 1554) then the method includes reading data from the read address with alternative read parameter(s), (e.g., at least one other Vref (e.g., Vref2)) to obtain read_data_retry 1562 and analyzing read_data_initial and read_data_retry to obtain a final result 1582 (e.g., to determine which data, if any, may be considered reliable).

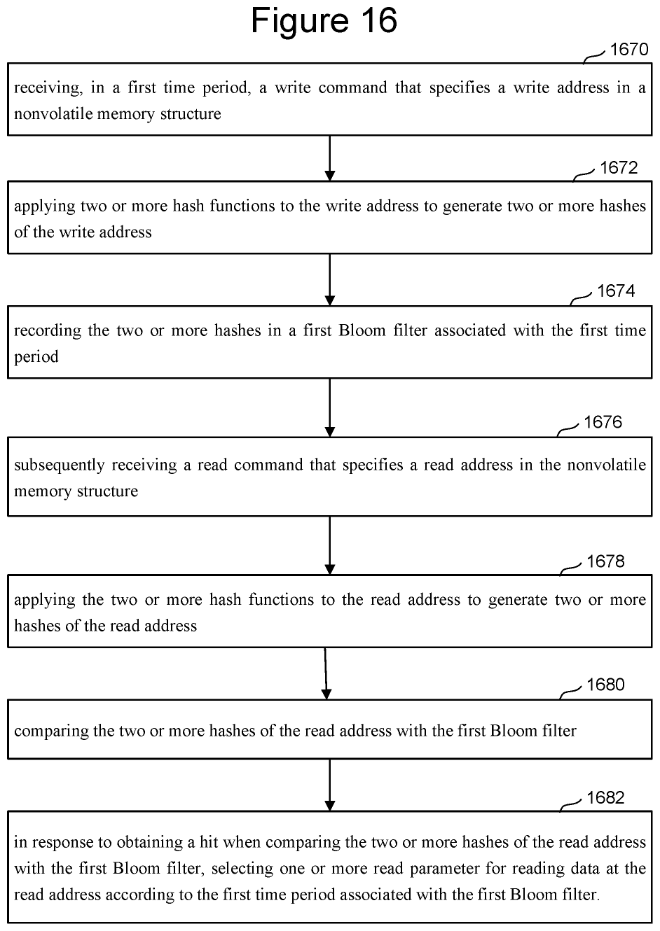

FIG. 15C shows an example of analysis of step 1582 in the form of a table that shows different possible conditions (e.g., found by ECC decoding) for read_data_initial (left column) and read_data_retry (middle column) with corresponding final read results for each combination (right column). For example, if both read_data_initial and read_data_retry are correctable with the same result, then read_data_initial (or read_data_retry) may be used as the final read result. If both read_data_initial and read_data_retry are correctable but with different results, then the data may be considered uncorrectable (e.g., other read conditions may be applied or some other way may be used to recover the data). If one of read_data_initial and read_data_retry is correctable and the other is uncorrectable then the correctable copy may be used as the final read result. If both read_data_initial and read_data_retry are uncorrectable then the data may be considered uncorrectable. FIG. 16 shows an example of a method that includes receiving, in a first time period, a write command that specifies a write address in a nonvolatile memory structure 1670, applying two or more hash functions to the write address to generate two or more hashes of the write address 1672 and recording the two or more hashes in a first Bloom filter associated with the first time period 1674 (e.g., HashX (AddrAAAA), HashY (AddrAAAA) and HashZ (AddrAAAA) recorded in Bloom filter 1300. The method further includes, subsequently receiving a read command that specifies a read address in the nonvolatile memory structure 1676, applying the two or more hash functions to the read address to generate two or more hashes of the read address 1678, comparing the two or more hashes of the read address with the first Bloom filter 1680 (e.g., comparing bit string 1302 with Bloom filter 1300 in FIG. 13C) and in response to obtaining a hit when comparing the two or more hashes of the read address with the first Bloom filter, selecting one or more read parameter for reading data at the read address according to the first time period associated with the first Bloom filter (e.g., selecting Vref1 corresponding to initial period 1140 as shown in FIG. 11A).

The methods illustrated in FIGS. 14-16 may be implemented using any appropriate circuits. For example, control circuits 1012 including Bloom filter based drift tracker 1014 may be used to implement some or all steps described and may be considered an example of means for applying a plurality of Bloom filters to write addresses of the nonvolatile memory cell structure, each Bloom filter corresponding to a respective period, each Bloom filter having a corresponding plurality of hash functions to apply to write addresses received in the respective period of the Bloom filter to generate hashes to populate the Bloom filter, applying the plurality of Bloom filters to a read address to determine whether the read address corresponds to a write address used to populate a Bloom filter of the plurality of Bloom filters and reading data at the read address according to the determination.

According to aspects of the present technology, apparatus includes one or more control circuit configured to connect to a nonvolatile memory cell structure that includes nonvolatile memory cells. The one or more control circuit is configured to: receive a plurality of write commands, each write command specifying a write address in the nonvolatile memory cell structure, apply a plurality of Bloom filters to the write addresses, each Bloom filter corresponding to a respective period, each Bloom filter having a plurality of hash functions to be applied to write addresses received in the respective period of the Bloom filter to generate hashes to populate the Bloom filter.

In one or more example of the above apparatus, the one or more control circuit is further configured to receive a plurality of read commands, each read command specifying a read address in the nonvolatile memory cell structure and apply the plurality of Bloom filters to a read address to determine whether the read address corresponds to a write address used to populate any Bloom filter of the plurality of Bloom filters.

In one or more example of the above apparatus, the one or more control circuit is further configured to perform a read operation at a location in the nonvolatile memory cell structure indicated by the read address.

In one or more example of the above apparatus, the one or more control circuit is further configured to adjust read parameters of the read operation according to the determination as to whether the read address corresponds to a write address used to populate any Bloom filter of the plurality of Bloom filters.

In one or more example of the above apparatus, the one or more control circuit is further configured to set a read reference voltage to a first reference voltage for any read address corresponding to a write address used to populate any Bloom filter of the plurality of Bloom filters and to set the read reference voltage to a second reference voltage for any read address not corresponding to any write address used to populate any Bloom filter of the plurality of Bloom filters.

In one or more example of the above apparatus, the one or more control circuit is configured to set a read reference voltage to a first voltage for any read address corresponding to a write address used to populate a Bloom filter of a first subset of the plurality of Bloom filters, set the read reference voltage to a second voltage for any read address corresponding to a write address used to populate a Bloom filter of a second subset of the plurality of Bloom filters, and set the read reference voltage to a third voltage for any read address not corresponding to any write address used to populate any Bloom filter of the plurality of Bloom filters.

In one or more example of the above apparatus, the one or more control circuit is configured to apply only an active Bloom filter of the plurality of Bloom filters to a write address received in a period of the active Bloom filter and at the end of the period of the active Bloom filter to erase an oldest Bloom filter of the plurality of Bloom filters and designate an erased Bloom filter as the active Bloom filter for a subsequent period.

In one or more example of the above apparatus, the nonvolatile memory cell structure is a cross-point memory cell structure that includes two or more levels of nonvolatile memory cells.

In one or more example of the above apparatus, the nonvolatile memory cells are Phase Change Memory (PCM) or Selector-Only Memory (SOM) memory cells.

According to another set of aspects, a method includes receiving, in a first time period, a write command that specifies a write address in a nonvolatile memory structure; applying two or more hash functions to the write address to generate two or more hashes of the write address; recording the two or more hashes in a first Bloom filter associated with the first time period; subsequently receiving a read command that specifies a read address in the nonvolatile memory structure; applying the two or more hash functions to the read address to generate two or more hashes of the read address; comparing the two or more hashes of the read address with the first Bloom filter; and in response to obtaining a hit when comparing the two or more hashes of the read address with the first Bloom filter, selecting one or more read parameter for reading data at the read address according to the first time period associated with the first Bloom filter.

In one or more example, the above method further includes applying the two or more hash functions to all write address and recording resulting hashes in the first Bloom filter and in additional Bloom filters associated with additional time periods.

In one or more example, the above method further includes applying the two or more hash functions to all read addresses and comparing the resulting hashes with the first Bloom filter and the additional Bloom filters.

In one or more example, the above method further includes in response to failing to obtain a hit when comparing hash functions of an additional read address with the first Bloom filter and the additional Bloom filters, selecting the one or more read parameter for reading data at the additional read address according to an elapsed time greater than the time periods of the first Bloom filter and the additional Bloom filters.

In one or more example of the above method, selecting the one or more read parameter for reading data at the read address according to the first time period associated with the first Bloom filter includes selecting a first reference voltage to compare with a voltage across a memory cell at the read address; and selecting the one or more read parameter for reading data at the additional read address according to an elapsed time greater than the time periods of the first Bloom filter and the additional Bloom filters includes selecting a second reference voltage to compare with a voltage across a memory cell at the additional read address.

In one or more example, the above method further includes maintaining the first Bloom filter as an active Bloom filter for recording hashes of all write addresses received in the first time period; maintaining a plurality of additional Bloom filters as archived Bloom filters for comparison with hashes of all read addresses received; and at the end of the first time period, designating the first Bloom filter as archived, designating an oldest archived Bloom filter as unused and designating an unused Bloom filter as an active Bloom filter.

In one or more example, the above method further includes performing Error Correction Code (ECC) decoding of data read from the read address with the selected one or more read parameter; and in response to obtaining an error rate above a predetermined error rate, changing the one or more read parameter and performing an additional read of data from the read address with alternative read parameters.

In one or more example of the above method, the method further includes determining whether reliability of the data read from the read address with the selected one or more read parameter exceeds a minimum reliability level; in response to determining that the data read from the read address with the selected one or more read parameter does not exceed the minimum reliability level, changing the one or more read parameter and performing an additional read of data from the read address with one or more alternative read parameter; and analyzing the data read from the read address with the selected one or more read parameter and the data read from the read address with the one or more alternative read parameter to obtain a final read result

In another set of aspects, a system includes a nonvolatile memory cell structure that includes nonvolatile memory cells each having a programmable resistive element; and means for applying a plurality of Bloom filters to write addresses of the nonvolatile memory cell structure, each Bloom filter corresponding to a respective period, each Bloom filter having a corresponding plurality of hash functions to apply to write addresses received in the respective period of the Bloom filter to generate hashes to populate the Bloom filter, applying the plurality of Bloom filters to a read address to determine whether the read address corresponds to a write address used to populate a Bloom filter of the plurality of Bloom filters and reading data at the read address according to the determination.

In one or more example, the above system is configured to read the data using a first reference voltage for any read address corresponding to a write address used to populate any Bloom filter of the plurality of Bloom filters and to read the data using a second reference voltage for any read address not corresponding to any write address used to populate any Bloom filter of the plurality of Bloom filters.

In one or more example of the above system, the nonvolatile memory cell structure is a Phase Change Memory (PCM) or Selector-Only Memory (SOM) structure.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
one or more control circuit configured to connect to a nonvolatile memory cell structure that includes nonvolatile memory cells, the one or more control circuit configured to:
receive a plurality of write commands, each write command specifying a write address in the nonvolatile memory cell structure, apply a plurality of Bloom filters to the write addresses, each Bloom filter corresponding to a respective period, each Bloom filter having a plurality of hash functions to be applied to write addresses received in the respective period of the Bloom filter to generate hashes to populate the Bloom filter.

2. The apparatus of claim 1, wherein the one or more control circuit is further configured to receive a plurality of read commands, each read command specifying a read address in the nonvolatile memory cell structure and apply the plurality of Bloom filters to a read address to determine whether the read address corresponds to a write address used to populate any Bloom filter of the plurality of Bloom filters.

3. The apparatus of claim 2, wherein the one or more control circuit is further configured to perform a read operation at a location in the nonvolatile memory cell structure indicated by the read address.

4. The apparatus of claim 3, wherein the one or more control circuit is further configured to adjust read parameters of the read operation according to the determination as to whether the read address corresponds to a write address used to populate any Bloom filter of the plurality of Bloom filters.

5. The apparatus of claim 4, wherein the one or more control circuit is further configured to set a read reference voltage to a first reference voltage for any read address corresponding to a write address used to populate any Bloom filter of the plurality of Bloom filters and to set the read reference voltage to a second reference voltage for any read address not corresponding to any write address used to populate any Bloom filter of the plurality of Bloom filters.

6. The apparatus of claim 4, wherein the one or more control circuit is configured to set a read reference voltage to a first voltage for any read address corresponding to a write address used to populate a Bloom filter of a first subset of the plurality of Bloom filters, set the read reference voltage to a second voltage for any read address corresponding to a write address used to populate a Bloom filter of a second subset of the plurality of Bloom filters, and set the read reference voltage to a third voltage for any read address not corresponding to any write address used to populate any Bloom filter of the plurality of Bloom filters.

7. The apparatus of claim 1, wherein the one or more control circuit is configured to apply only an active Bloom filter of the plurality of Bloom filters to a write address received in a period of the active Bloom filter and at the end of the period of the active Bloom filter to erase an oldest Bloom filter of the plurality of Bloom filters and designate an erased Bloom filter as the active Bloom filter for a subsequent period.

8. The apparatus of claim 1, wherein the nonvolatile memory cell structure is a cross-point memory cell structure that includes two or more levels of nonvolatile memory cells.

9. The apparatus of claim 8, wherein the nonvolatile memory cells are Phase Change Memory (PCM) or Selector-Only Memory (SOM) memory cells.

10. A method, comprising:
receiving, in a first time period, a write command that specifies a write address in a nonvolatile memory structure;
applying two or more hash functions to the write address to generate two or more hashes of the write address;
recording the two or more hashes in a first Bloom filter associated with the first time period;
subsequently receiving a read command that specifies a read address in the nonvolatile memory structure;
applying the two or more hash functions to the read address to generate two or more hashes of the read address;
comparing the two or more hashes of the read address with the first Bloom filter; and
in response to obtaining a hit when comparing the two or more hashes of the read address with the first Bloom filter, selecting one or more read parameter for reading data at the read address according to the first time period associated with the first Bloom filter.

11. The method of claim 10, further comprising:
applying the two or more hash functions to all write address and recording resulting hashes in the first Bloom filter and in additional Bloom filters associated with additional time periods.

12. The method of claim 11, further comprising:
applying the two or more hash functions to all read addresses and comparing the resulting hashes with the first Bloom filter and the additional Bloom filters.

13. The method of claim 12, further comprising:
in response to failing to obtain a hit when comparing hash functions of an additional read address with the first Bloom filter and the additional Bloom filters, selecting the one or more read parameter for reading data at the additional read address according to an elapsed time greater than the time periods of the first Bloom filter and the additional Bloom filters.

14. The method of claim 13, wherein:
selecting the one or more read parameter for reading data at the read address according to the first time period associated with the first Bloom filter includes selecting a first reference voltage to compare with a voltage across a memory cell at the read address; and
selecting the one or more read parameter for reading data at the additional read address according to an elapsed time greater than the time periods of the first Bloom filter and the additional Bloom filters includes selecting a second reference voltage to compare with a voltage across a memory cell at the additional read address.

15. The method of claim 10, further comprising:
maintaining the first Bloom filter as an active Bloom filter for recording hashes of all write addresses received in the first time period;
maintaining a plurality of additional Bloom filters as archived Bloom filters for comparison with hashes of all read addresses received; and
at the end of the first time period, designating the first Bloom filter as archived, designating an oldest archived Bloom filter as unused and designating an unused Bloom filter as an active Bloom filter.

16. The method of claim 10, further comprising:
performing Error Correction Code (ECC) decoding of data read from the read address with the selected one or more read parameter; and
in response to obtaining an error rate above a predetermined error rate, changing the one or more read parameter and performing an additional read of data from the read address with alternative read parameters.

17. The method of claim 10, further comprising:
determining whether reliability of the data read from the read address with the selected one or more read parameter exceeds a minimum reliability level;
in response to determining that the data read from the read address with the selected one or more read parameter does not exceed the minimum reliability level, changing the one or more read parameter and performing an additional read of data from the read address with one or more alternative read parameter; and
analyzing the data read from the read address with the selected one or more read parameter and the data read from the read address with the one or more alternative read parameter to obtain a final read result.

18. A system, comprising:
a nonvolatile memory cell structure that includes nonvolatile memory cells each having a programmable resistive element; and
means for applying a plurality of Bloom filters to write addresses of the nonvolatile memory cell structure, each Bloom filter corresponding to a respective period, each Bloom filter having a corresponding plurality of hash functions to apply to write addresses received in the respective period of the Bloom filter to generate hashes to populate the Bloom filter, applying the plurality of Bloom filters to a read address to determine whether the read address corresponds to a write address used to populate a Bloom filter of the plurality of Bloom filters and reading data at the read address according to the determination.

19. The system of claim 18, wherein the system is configured to read the data using a first reference voltage for any read address corresponding to a write address used to populate any Bloom filter of the plurality of Bloom filters and to read the data using a second reference voltage for any read address not corresponding to any write address used to populate any Bloom filter of the plurality of Bloom filters.

20. The system of claim 18, wherein the nonvolatile memory cell structure is a Phase Change Memory (PCM) or Selector-Only Memory (SOM) structure.
